(19) United States
(12) Patent Application Publication
(10) Pub. No.: US 2011/0303444 A1
(43) Pub. Date: Dec. 15, 2011

(54) LAMINATED CIRCUIT BOARD, BONDING SHEET, LAMINATED-CIRCUIT-BOARD PRODUCING METHOD, AND BONDING -SHEET PRODUCING METHOD

(75) Inventor: Hideaki YOSHIMURA, Kawasaki (JP)

(73) Assignee: FUJITSU LIMITED, Kawasaki-shi (JP)

(21) Appl. No.: 13/074,643

(22) Filed: Mar. 29, 2011

(30) Foreign Application Priority Data
Jun. 10, 2010 (JP) 2010-133406

(51) Int. Cl. H05K 1/09; H05K 1/11; H05K 3/20; H05K 1/00

(52) U.S. Cl. 174/257; 174/250; 174/266; 29/831

(57) ABSTRACT

A laminated circuit board includes a first wiring board including a first land formed thereon; a second wiring board including a second land formed thereon; and a bonding layer interposed between the first wiring board and the second wiring board, wherein the bonding layer electrically connects the first land to the second land with a conductive material, wherein the bonding layer has a front-side layer, a rear-side layer, and a middle layer, and the middle layer has a higher viscosity than the front-side layer and the rear-side layer.

### CROSS-REFERENCE TO RELATED APPLICATIONS

This application is based upon and claims the benefit of priority of the prior Japanese Patent Application No. 2010-133406, filed on Jun. 10, 2010, the entire contents of which are incorporated herein by reference.

### FIELD

The embodiments discussed herein are directed to a laminated circuit board, a bonding sheet, a laminated-circuit-board producing method, and a bonding-sheet producing method.

### BACKGROUND

Regarding a well-known build-up board-processing process, such as an additive process and a semi-additive process, as the number of layers increases, the number of producing steps increases largely and the yield ratio decreases remarkably. As a measure to solve the above problems, a lamination technique gathers attention that is used to connect separately-produced board layers with a conductive paste and a conducting material in one process.

As a material of vias on a board stacked, copper vias and through-holes are used that are formed by techniques, such as nonelectrolytic plating and electrolytic plating. Moreover, techniques to bond boards together include a technique to connect lands of the boards with a conductive paste and a technique to bond the boards together with a conducting material that contains low-melting-point powders. Moreover, techniques to bond an electronic component, such as a ball grid array (BGA), and a board together include a bonding technique using a solder material, a bonding material, such as the above conducting material, etc.

A method of producing a board that is to be bonded to another board is described below with reference to FIG. 8 in which the board is produced based on a typical multi-layered board. FIG. 8 is a schematic diagram that illustrates an example of a conventional method of producing a board that is to be bonded to another board. As illustrated in FIG. 8, to form a through-hole plating power supply and a surface pattern, a hold is formed on a multi-layered board 1 that has a copper foil layer on the surface where a wire 2 is present and then the through-hole is plated to cover the exposed surface. After that, the hole is filled with an epoxy-based resin 3 and the board is then polished. After that, the board is plated to cover the entire surface and then patterning is conducted. Thus, the board that is to be bonded to another board is produced.

Boards that are produced in the above manner are bonded together with a bonding material and lands 4 formed on the respective boards are electrically connected to each other via a conducting material (conductive filler) in a through-hole formed on the bonding material. Thus, by bonding the individual multi-layered boards 1 together, one board is produced.

However, if a board to be bonded to another board is produced in the above-described typical method as illustrated in FIG. 8, the surface of the board 1 is made up of three layers that include the copper foil layer, the through-hole plated layer, and the entire-surface plated layer; therefore, the wiring patterns and the lands formed on the surface of the board are thick. When boards each having such thick wiring patterns and lands are bonded together, in order to accurately bond the wires or the lands together, it is to use a high-viscosity bonding material 7. However, it is difficult to spread the high-viscosity bonding material 7 over the entire bonding surface. This increases the possibility that a void 8 occurs in a bonding layer that bonds the board 1 and a board 5 together as illustrated in FIG. 9. FIG. 9 is a schematic diagram of an example where voids occur.

If a board having the void 8 is used in an electronic component, a defective product is likely to be produced. Therefore, bonding techniques for producing a board with no void 8 are in common use, such as a technique of bonding boards with a bonding material that is viscous but easy to spread over the entire bonding surface, i.e., has a high flow rate.
Patent Document 1: Japanese Laid-open Patent Publication No. 2005-123436
Patent Document 2: Japanese Laid-open Patent Publication No. 11-204939
Patent Document 3: Japanese Laid-open Patent Publication No. 09-298361
Patent Document 4: Japanese Patent No. 2603053

However, even if a high flow-rate bonding material is used as the bonding material 7, there is the possibility that, when a through-hole is formed on the bonding material and the through-hole is then filled with a conducting material 6, the conducting material 6 goes out of the through-hole and the lands fail to be electrically connected to each other.

For example, due to a pressure that is applied to bond the boards together, as illustrated in FIG. 10, the conducting material 6 goes out of the through-hole to the bonding surface in accordance with movement of the evenly coverable bonding material 7. Because no conducting material 6 is present between the lands, the lands are disconnected. FIG. 10 is a schematic diagram that illustrates an example where the bonding material for connecting the lands moves to incorrect positions.

As described above, if boards are bonded together with a high-viscosity bonding material, the conducting material is in the through-hole and, therefore, the lands are connected but there is the possibility that a void occurs and a defective board is produced. On the other hand, if boards are bonded together with a high flow-rate bonding material, no void will occur but there is the possibility that the conducting material goes out of the through-hole and a board is produced with the lands being disconnected.

### SUMMARY

According to an aspect of an embodiment of the invention, a laminated circuit board includes a first wiring board including a first land formed thereon; a second wiring board including a second land formed thereon; and a bonding layer interposed between the first wiring board and the second wiring board, wherein the bonding layer electrically connects the first land to the second land with a conductive material, wherein the bonding layer has a front-side layer, a rear-side layer, and a middle layer, and the middle layer has a higher viscosity than the front-side layer and the rear-side layer.

The object and advantages of the embodiment will be realized and attained by means of the elements and combinations particularly pointed out in the claims.

It is to be understood that both the foregoing general description and the following detailed description are exemplary and explanatory and are not restrictive of the embodiment, as claimed.

### BRIEF DESCRIPTION OF DRAWINGS

FIG. 1 is a cross-sectional view of a laminated circuit board according to the first embodiment;

FIG. 2 is a schematic diagram that illustrates an example of a process for producing one bonding sheet that is a layer of a bonding layer;

FIG. 3 is a schematic diagram that illustrates an example of a process for bonding three bonding sheets together, thereby producing a bonding layer;

FIG. 4 is a schematic diagram that illustrates another example of a process for bonding three bonding sheets together, thereby producing a bonding layer;

FIG. 5 is a schematic diagram that illustrates a process for bonding single-layered boards together, thereby producing one laminated circuit board;

FIG. 6 is a schematic diagram that illustrates connection between lands;

FIG. 7 is a graph that proves usability of the laminated circuit board described in the present embodiment;

FIG. 8 is a schematic diagram that illustrates an example of a conventional method of producing a board that is to be bonded to another board;

FIG. 9 is a schematic diagram of an example where voids occur; and

FIG. 10 is a schematic diagram that illustrates an example where a bonding material for connecting lands moves to incorrect positions.

### DESCRIPTION OF EMBODIMENTS

Preferred embodiments of the present invention will be explained with reference to accompanying drawings. It is noted that the present invention is not limited to the following embodiments.

### [a] First Embodiment

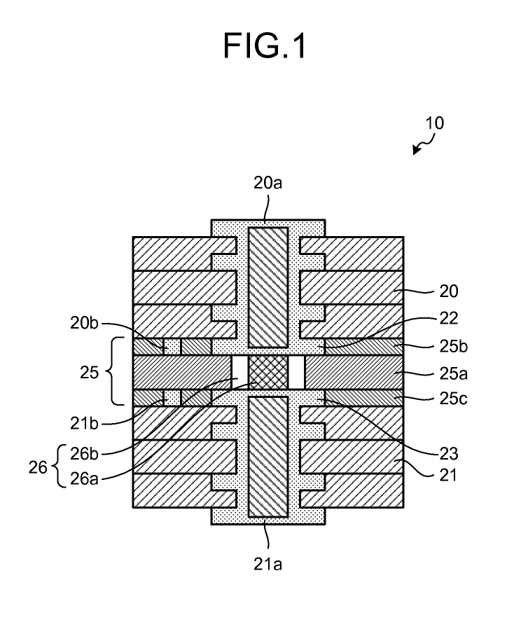

FIG. 1 is a cross-sectional view of a laminated circuit board according to the first embodiment. As illustrated in FIG. 1, a laminated circuit board 10 is produced by electrically connecting a multi-layered board 20 to a multi-layered board 21.

The multi-layered board 20 includes insulators and patterns stacked and has a plurality of stacked boards having a copper foil layer on the surface for power supply of a through-hole 20a and surface patterning. The multi-layered board 20 is produced to include the through-hole 20a, a land 22, and a wire 20b. The through-hole 20a is used to electrically connect circuits on different layers and filled with an epoxy-based resin.

The land 22 is a copper foil or similar. When the multi-layered board 20 that has the through-hole 20a is bonded to the multi-layered board 21 that has a through-hole 21a, thereby producing one board, the land 22 electrically connects the multi-layered boards 20 and 21. The wire 20b is a wire being laid on a surface of the multi-layered board 20 that is connected to the multi-layered board 21. The multi-layered board 21 has the through-hole 21a, a land 23, and a wire 21b. The components of the multi-layered board 21 are the same as those of the multi-layered board 20; therefore, the same description is not repeated.

The laminated circuit board 10 is produced by electrically connecting the multi-layered board 20 to the multi-layered board 21 via a bonding layer 25. The bonding layer 25 is a three-layered bonding sheet that is made of a bonding material 25a, a bonding material 25b, and a bonding material 25c.

The bonding material 25a is a middle layer of the bonding layer 25, being laid between the bonding material 25b and the bonding material 25c. The bonding material 25a is, for example, a bonding sheet made of a dielectric material having a higher viscosity than those of dielectric materials of the bonding materials 25b and 25c. The bonding material 25a is made of, for example, a typical epoxy-based material and can be made of various materials, such as polyimide-based material and liquid-crystal polymer. Moreover, when temperature increase is taken into consideration that occurs when a pressure is applied to bond the multi-layered boards 20 and 21 together, the bonding material 25a preferably has the viscosity 3000 Pa·s (Pascal-second) or higher.

The bonding material 25b is a front-side layer of the bonding layer 25 that is bonded to the multi-layered board 20. The bonding material 25b is a bonding sheet made of a dielectric material that has a viscosity lower than that of the dielectric material of the bonding material 25a. The bonding material 25b is, for example, the same material as that of the bonding material 25a and preferably has the viscosity 1000 Pa·s or higher. The bonding material 25c is a rear-side layer of the bonding layer 25 that is bonded to the multi-layered board 21. The bonding material 25c is a bonding sheet made of a dielectric material that has a viscosity lower than that of the dielectric material of the bonding material 25a. The bonding material 25c is, for example, the same material as the bonding material 25a and preferably has the viscosity 1000 Pa·s or higher, i.e., the same level as the bonding material 25b has.

A through-hole is formed on the bonding layer 25 and then the through-hole is filled with a conducting material 26 to electrically connect the land 22 to the land 23. The conducting material 26 is a mixture of metallic alloy powders, an activating material, and a bonding resin. The metallic alloy powders form the land 22, the land 23, and an inter-metal compound and bond them together. The activating material allows the metallic alloy powders to be one piece of metallic alloy. The bonding resin bonds the metallic alloy powders and the activating material and gives viscosity and printability to the mixture. The bonding resin is a thermosetting resin that is hardened when it is combined with the activating material.

During the process in which the metallic alloy powders melt at a lamination temperature into one piece, in the conducting material 26, the melted metallic alloy is separated from the thermosetting bonding resin and shapes a pillar of a metallic alloy 26a at the center. The conducting material 26 is shaped a double pillar that is the pillar of the metallic alloy 26a covered with a hardened bonding resin 26b. Thus, the laminated circuit board 10 is produced as a laminate of an electronic component having via connection structure in which the multi-layered board 20 is electrically connected to the multi-layered board 21.

As described above, in the first embodiment, because the multi-layered board 20 is bonded to the multi-layered board 21 with the bonding material 25b or the bonding material 25c that is viscous but has a high flow rate, occurrence of voids is prevented. Moreover, because the peripheral of the through-hole filled with the conducting material 26 is covered with the high-viscosity bonding material 25a, the conducting material 26 remains inside the through-hole when a pressure is applied to bond the multi-layered boards 20 and 21 together. The conducting material is present between the lands and, thus, the lands are electrically connected. As described above, in the first embodiment, the lands are bonded together, preventing occurrence of voids.

### [b] Second Embodiment

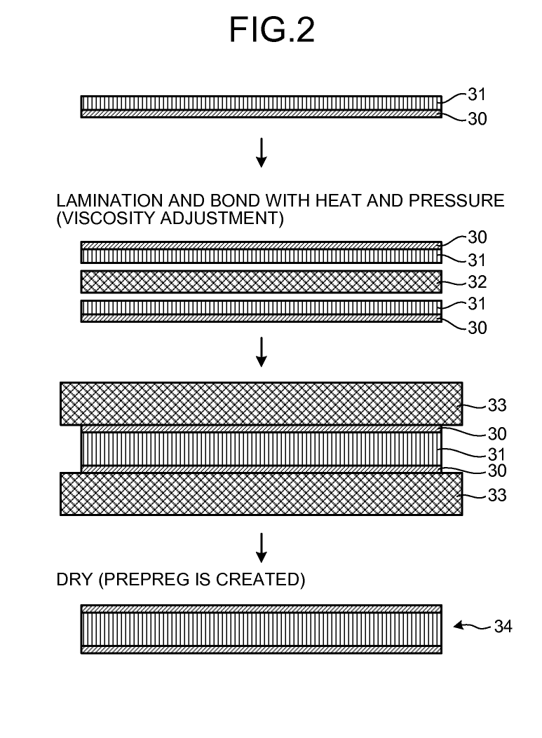

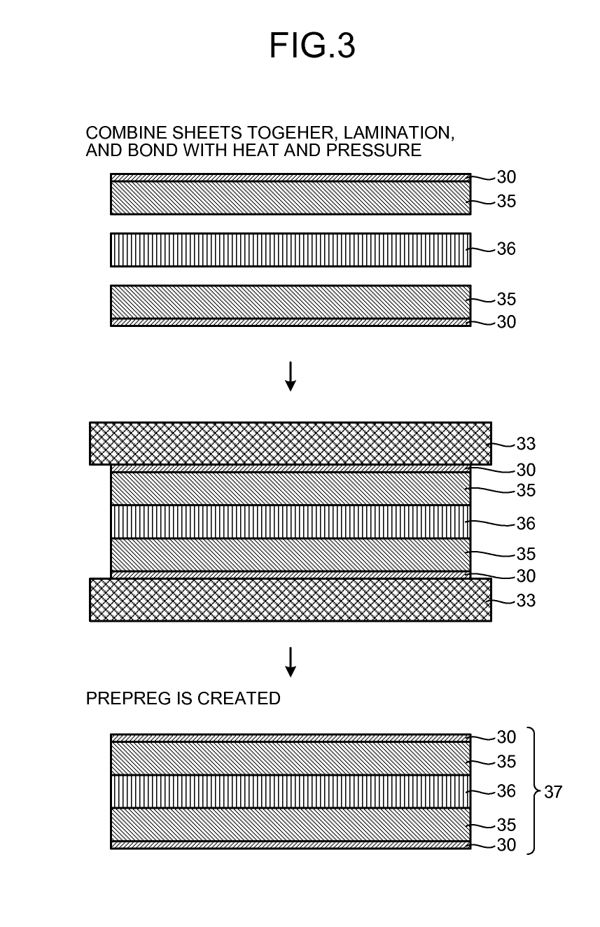

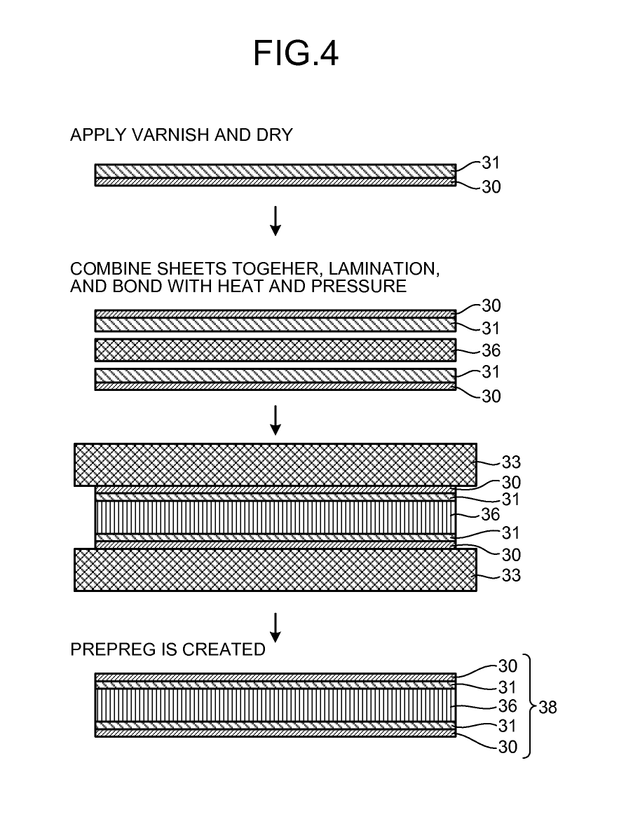

A method of producing the bonding layer 25 (bonding sheet) illustrated in FIG. 1 is described below with reference to FIGS. 2 to 4. FIG. 2 is a schematic diagram that illustrates an example of a process for producing one bonding sheet that is a layer of the bonding layer. FIGS. 3 and 4 are schematic diagrams that illustrate an example of a process for bonding three bonding sheets together, thereby producing a bonding layer. The process for producing the bonding layer can be performed manually or automatically by using a producing device. In the following example, the bonding layer is produced by a producing device.

As illustrated in FIG. 2, the producing device applies an epoxy resin 31, such as varnish, on a polyester (PET) film 30. For example, the producing device applies the epoxy resin 31 on the PET film 30 having the thickness 50 μm in such a manner that the layer thickness of the epoxy resin 31 is 100 μm. Moreover, in order to produce a product having a high viscosity, the producing device adds silica filler powders to the epoxy resin 31. The producing device further add a silane coupler, which is effective to increase the coupling efficiency of the epoxy resin 31, and a solvent that contains toluene and methyl ethyl ketone (MEK) as a diluting solution to the epoxy resin 31 and mixes them. The producing device applies the thus created solution as the epoxy resin 31.

After that, the producing device inserts, for example, a glass fiber sheet 32 having the thickness about 100 μm between two PET films 30 dried with a fired heater in such a manner that the glass fiber sheet 32 is in contact with the surfaces covered with the epoxy resin 31 and then applies heat and pressure by holding them between a pair of heating plates 33, thereby producing a bonding sheet or a prepreg 34. Thus, the producing device produces one bonding sheet that is a layer of the bonding layer 25. The glass fiber sheet 32 is, for example, fabric cloth of glass fibers.

As described above, the producing device produces one bonding sheet in the above technique. The producing device produces, in the same technique, a bonding sheet that is used as the middle layer of the bonding layer 25 and bonding sheets that are used as the front-side layer and the rear-side layer. In other words, the producing device produces bonding sheets having different viscosities.

The producing device can adjust the viscosity by, for example, adding a filler (either filler is useful an inorganic filler, such as silica, or an organic filler) and using impregnated glass fiber (either fiber is useful an inorganic fiber or an organic fiber) and produce the high-viscosity bonding sheet. Moreover, the producing device can produce a high-viscosity bonding sheet by changing the degree of polymerization of resin, thereby adjusting the gel time. The producing device can use some other well-known techniques, such as a technique of using a material the viscosity of which is increased by increasing the molecular weight and adding a rigid structure, and a technique of mixing together materials solid at the room temperature, such as a novolac-type resin.

The producing device then produces lowly adjusted viscosity prepregs 35 that has a viscosity adjusted to a low level and a highly adjusted viscosity prepreg 36 that has a viscosity adjusted to a high level in the above technique. After that, as illustrated in FIG. 3, the producing device inserts the highly adjusted viscosity prepreg 36 between the two lowly adjusted viscosity prepregs 35 and applies heat and pressure with the heat plates 33, thereby producing a three-layered prepreg 37 as the bonding layer 25.

Although, with reference to FIG. 3, the technique of producing individual prepregs and then bonding the prepregs together, it is allowable to produce the bonding layer 25 by using some other techniques. For example, as illustrated in FIG. 4, the producing device applies the epoxy resin 31, such as varnish, on the PET film 30. The producing device produces the highly adjusted viscosity prepreg 36 that has the viscosity adjusted to a high level in the above technique. After that, the producing device inserts the highly adjusted viscosity prepreg 36 between the two PET films 30 dried with the fired heater in such a manner that the highly adjusted viscosity prepreg 36 is in contact with the surfaces coated with the epoxy resin 31 and then applies heat and pressure by holding them between the heat plates 33, thereby producing a prepreg 38. The producing device then adjusts the resin layer formed on the surface of the prepreg 38 in such a manner that the viscosity of the epoxy resin on the surface is eventually adjusted to 1000 Pa·s or lower in the above viscosity adjusting method. Thus, the producing device produces the three-layered bonding layer 25.

Although, in the present embodiment, an inorganic glass fiber sheet is used, it is allowable to use an organic fiber sheet made of, for example, aramid. Moreover, it is allowable to produce prepregs directly from something other than particular fiber sheets without performing a heat-and-pressure bonding process.

Moreover, the high-viscosity middle layer can be multi-layered so long as the viscosity of the middle layer is 3000 Pa·s. The materials of layers making up the multi-layered high-viscosity layer can be different or the same. It is possible to produce such a multi-layer in the technique described above with reference to FIG. 3 of producing individual prepregs and then bonding them together or the technique described above with reference to FIG. 4 of bonding layers sequentially.

Moreover, although, in the present embodiment, the epoxy resin of the middle layer is applied on the PET film and then a prepreg is produced, the method is not limited thereto. Another technique is useful, such as a technique of producing an epoxy-resin plate by applying an epoxy resin on a heat-resistant material, such as a copper foil, then completely hardening it during a prepreg-creating step, and then etching the copper foil. Moreover, it is allowable to produce an epoxy-resin plate by creating a prepreg, then bonding the prepreg to a copper foil, then hardening the prepreg, and then etching the copper in the same manner, and then form bonding layers with the viscosity 1000 Pa·s or lower bonding layers on the front side and the rear side of the produced epoxy-resin plate, thus producing a three-layered plate. Moreover, although the material of the low-viscosity layers on the surfaces is the same as that of the middle layer, it is allowable to use another high flow-rate material, such as a film of a liquid resin.

### [c] Third Embodiment

The three-layered bonding layer (bonding sheet) in the first embodiment and the second embodiment can be used to not only bond multi-layered boards together but also bond single-layered boards together. Although, in the following example, single-layered boards are bonded together, it is allowable to bond a single-layered board and a multi-layered board together in the same manner. Moreover, although the following bonding-layer producing process can be performed manually or automatically by a certain producing device, the producing device performs the process in the following example.

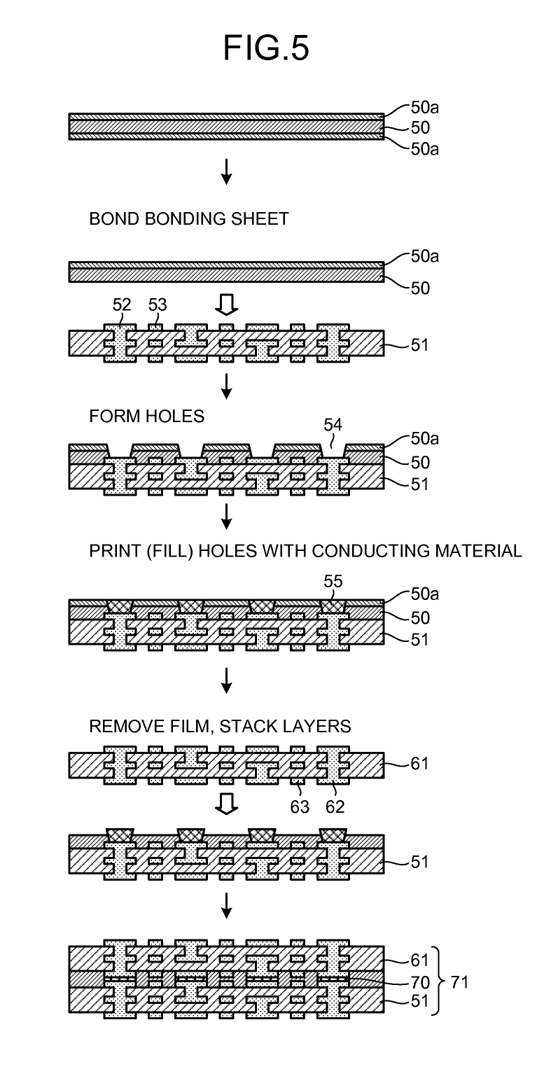

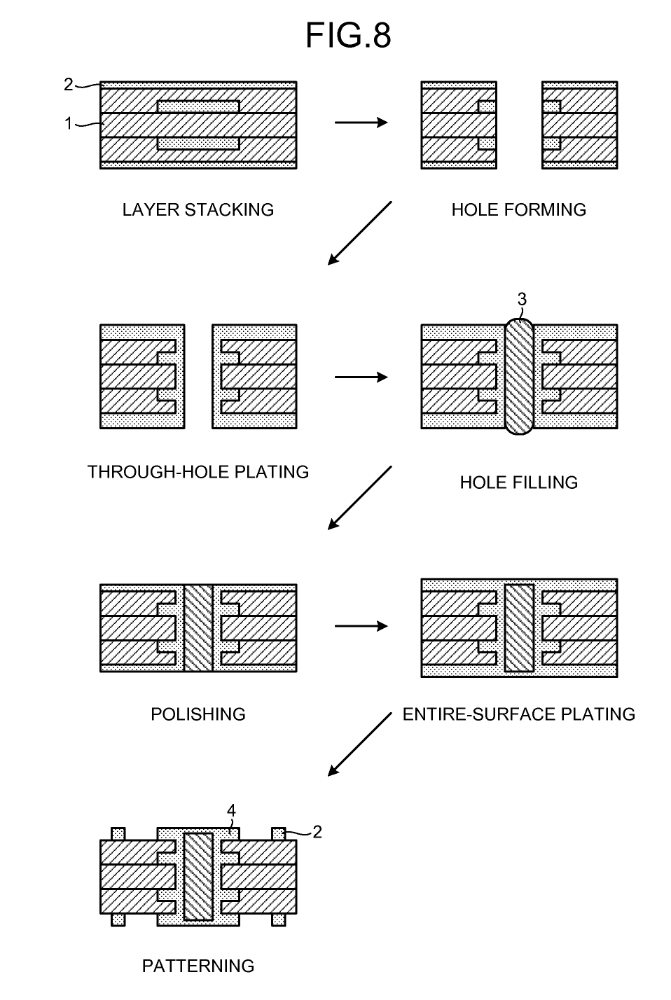

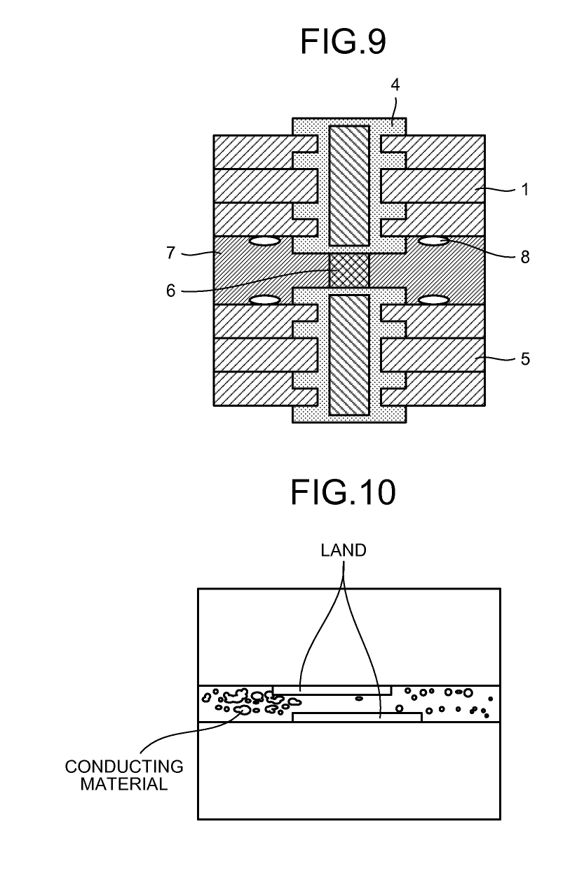

In the third embodiment, an example of bonding single-layered boards together is described with reference to FIG. 5. FIG. 5 is a schematic diagram that illustrates a process for bonding single-layered boards together, thereby producing one laminated circuit board. As illustrated in FIG. 5, the producing device bonds a three-layered bonding sheet 50 that is produced in the second embodiment to a single-layered board 51 that has a land 52 and a pattern 53 formed in a typical technique illustrated, for example, FIG. 8 (lamination). Because the both surfaces of the bonding sheet 50 are bonded with films 50a to maintain the viscosity level, the producing device removes one film 50a from either surface and bonds the surface to the single-layered board 51.

After that, the producing device forms a through-hole 54 on a part where the bonding sheet 50 and the land 52 are bonded together and fills (prints) the formed through-hole 54 with a conducting material 55. After that, the producing device removes the other film 50a from the bonding sheet 50, and bonds the other surface to a single-layered board 61 that has a land 62 and a pattern 63. The producing device bonds them together in such a manner that the land 62 of the single-layered board 61 is bonded to the conducting material 55.

Thus, the producing device bonds the single-layered boards 51 and 61 together, thereby producing a laminated circuit board 71 in which the land of the single-layered board 51 is electrically connected to the land of the single-layered board 61 through a connection via. Although, in the example according to the third embodiment, after the lamination, the through-hole 54 is formed on the bonding sheet 50 with a laser drill or similar, the embodiments are not limited thereto. For example, it is allowable to form the through-hole 54 on the bonding sheet 50 and then bond the bonding sheet 50 to the single-layered board 51. As described above, in the third embodiment, regardless whether boards are single-layered boards or multi-layered boards, usage of the bonding sheet disclosed in the present application prevents occurrence of voids and a laminated circuit board is thus produced with the lands being connected.

### [d] Fourth Embodiment

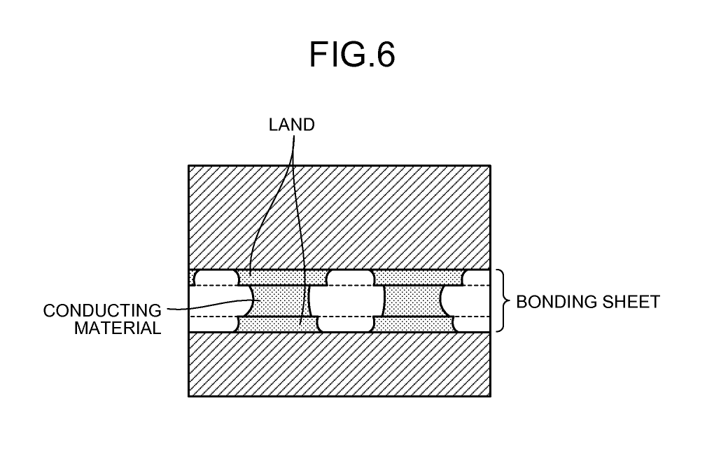

An example is described in the fourth embodiment about connection between the lands of the laminated circuit board that is produced in any of the first embodiment, the second embodiment, and the third embodiment. FIG. 6 is a schematic diagram that illustrates connection between the lands.

The conducting material that is present between the lands is a mixture of metallic alloy powders, an activating material, and a bonding resin. As illustrated in FIG. 6, during the process in which the metallic alloy powders melt at a lamination temperature into one piece, the metallic alloy is separated from the thermosetting bonding resin and shapes a connection via, while the separated bonding material component covers the peripheral of the block of the metal.

The thickness of the front-side layer and the rear-side layer of the bonding layer, i.e., the thickness of the front-side layer and the rear-side layer of the bonding sheet is preferably equal to the thickness of the wiring pattern surface on which the land is formed. Suppose a case, for example, that the bonding sheet has three layers or a low-viscosity first layer (front-side layer), a high-viscosity second layer (middle layer), and a low-viscosity third layer (rear-side layer) and the thickness of the lands to be connected is 20 μm. In this case, the thickness of each of the first layer and the third layer is preferably 20 μm.

Moreover, it is possible to adjust the thickness of each of the front-side surface and the rear-side surface of the bonding sheet to a value equal to or larger than the difference between the thickness of the wiring pattern surface on which the land is formed and the residual copper ratio of the wiring pattern surface that has the land. Suppose a case, for example, that the height of objects to be connected is about 110 μm, the thickness of the thickest lands is 70 μm, and the average of the thicknesses is 55 μm. In this case, the thickness of the low-viscosity resin layers that are on the front surface and the rear surface is preferably about 44 μm (55 μm×0.8) in accordance with the volume of the gap between the lands, the residual copper ratio of the lands being 20%. In this example, to be filled with the conducting material, a 300-μm through-hole is formed on the bonding sheet and the through-hole is then filled with the conducting material.

The connection via filled with the conducting material that connects the lands needs to have a small parasitic capacity, a small via diameter, and a short length, and have a conductor part with the same density. The via connection method include a method by using a resin that remains between fillers, a conductive bonding material such as silver filler, or a conductive paste such as copper paste. If the above methods are used, an area of the metallic part of the via that is in contact with the dielectric resin part is increased to a value larger than, if the block of metal has the same volume, an area of the block of material that is in contact with the resin part, which disadvantageously increases the parasitic capacity; therefore, the via connection method using a low-melting-point metal and a block of the metal is advantageous.

In the subject application, in order to decrease the via diameter, thereby decreasing the parasitic capacity, an activating agent component is contained in the conducting material to remove an oxide film from the surface of the low-melting-point metal. A bonding material component is also added such that the amount of the bonding material component is half or more of the total volume of the conducting material. The bonding material component reacts with the activating agent component and hardens and is useful to improve filling property. The metal part melts with heat during lamination and is separated from the resin part. The separated metal part gathers at the center and shapes a pillared via.

An example of the conducting material is described below that is used to form a via having a small parasitic capacity, a small via diameter, and a short length. For example, as the conducting material filling the through-hole, a low-melting-point alloy that is a mixture of tin-copper powders and tin-bismuth powders is used. The conducting material is added with an epoxy resin as a bonding material component, a hardener that hardens the epoxy resin, and an organic acid as both an activating agent and a metal-powder oxide-film removing agent. A thixotropy agent is added to the mixed powders to adjust the viscosity.

More particularly, in the conducting material, the volume ratio between the resin part and the metal powders is 3:2. The epoxy resin is, for example, bisphenol-A and bisphenol-F; the hardener is, for example, methyltetrahydrophthalic acid anhydride; the activating agent is, for example, the adipic acid; and the thixotropy agent is, for example, suberic acid amide. The reason for selecting the tin-bismuth powders to be the metal powders is that the melting point 138° C. is lower than the lamination temperature 170° C. The reason for selecting the tin-copper powders is to increase the cohesive power. The reason for adding an amount of copper to become supersaturated is to increase the melting point of the metallic via that is measured after the lamination.

As a result, the conducting material has a high cohesive power and the exactly separated bonding material gathers together surrounding the peripheral of the block of metal. Thus, the lands are connected via a metal surface small as much as possible with the via having a small parasitic capacity, which improves the connection reliability in terms of strength.

### [e] Fifth Embodiment

Although some embodiments of the present invention are described above, the present invention can be embodied otherwise. Other possible embodiments are described below.

Usability

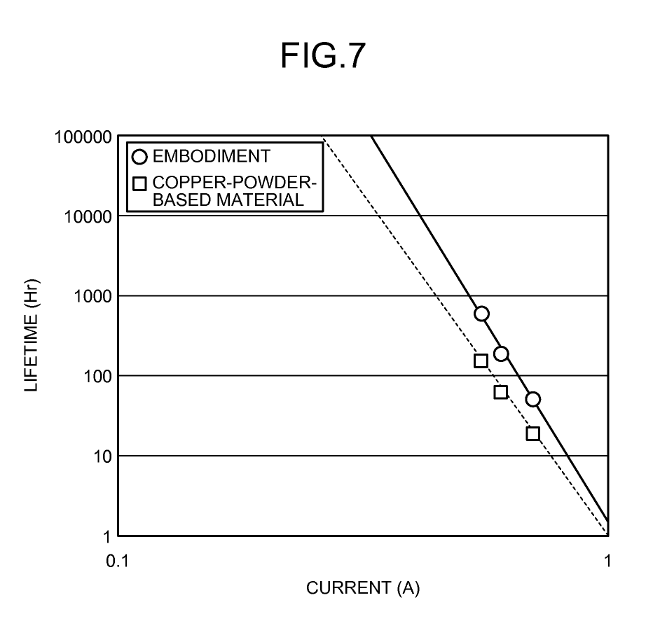

For example, although, in any of the first embodiment, the second embodiment, the third embodiment, and the fourth embodiment, occurrence of voids is decreased and the moved conducting material is also decreased, there is another merit such as an increase in the allowable current of a via (hereinafter, “via”) of a laminated circuit board that is produced according to any of the first embodiment, the second embodiment, the third embodiment, and the fourth embodiment. FIG. 7 is a graph of the relation between the current flowing at 150° C. and the short circuit duration of the via. The graph of FIG. 7 proves that, when the same current flows through a typical via made of a copper-powder-based material (hereinafter, “conventional via”) and the via, the lifetime of the via is longer than that of the conventional via. It means that, in any of the first embodiment, the second embodiment, the third embodiment, and the fourth embodiment, the allowable current of the via is increased. FIG. 7 is a graph that proves the usability of the laminated circuit board according to the embodiments.

In the three-layered bonding layer (bonding sheet) according to any of the first embodiment, the second embodiment, the third embodiment, and the fourth embodiment, the middle layer, the front-side layer, and the rear-side layer can be made of the same resin material but having different hardness. The middle layer can be a material with the front-side/rear-side layers that are hardened before the lamination.

Board

Although the above embodiments describe about a laminated circuit board that is produced by bonding multi-layered boards or single-layered boards together, the present invention is not limited thereto. In order to achieve the object, the technology disclosed herein is applicable to various components such as large scale integrations (LSIs), interposers, motherboards, various semiconductor elements, various package boards, various relay boards, and various circuit boards. Although, in the above embodiments, boards are bonded together, it is allowable to use the bonding sheet disclosed herein to bond an electric component and a board together or bond electric components together.

According to an embodiment of a laminated circuit board, a bonding sheet, a laminated-circuit-board producing method, and a bonding-sheet producing method disclosed in the subject application, lands are connected to each other without voids.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A laminated circuit board comprising:
a first wiring board including a first land formed thereon;
a second wiring board including a second land formed thereon; and
a bonding layer interposed between the first wiring board and the second wiring board, wherein the bonding layer electrically connects the first land to the second land with a conductive material, wherein
the bonding layer has a front-side layer, a rear-side layer, and a middle layer, and
the middle layer has a higher viscosity than the front-side layer and the rear-side layer.

2. The laminated circuit board according to claim 1, wherein thicknesses of the front-side layer and the rear-side layer of the bonding layer are equal to a thickness of a wiring pattern surface on which the first land or the second land is formed.

3. The laminated circuit board according to claim 1, wherein thicknesses of the front-side layer and the rear-side layer of the bonding layer are equal to or larger than a difference between a thickness of a wiring pattern surface on which the first land or the second land is formed and a residual copper ratio of a wiring pattern surface that has the first land or the second land.

4. The laminated circuit board according to claim 1, wherein the conductive material is a mixture of a metallic alloy powder, an activating material, and a bonding resin, wherein
the metallic alloy powder shapes the first land or the second land and an inter-metal compound and bond the first land and the second land together,
the activating material is used to convert the metallic alloy powder into a piece of metallic alloy,
the bonding resin is used to mix the metallic alloy powder and the activating material and give viscosity and printability, and
the bonding resin reacts with the activating material and hardens.

5. A bonding sheet interposed between a first wiring board including a first land formed thereon and a second wiring board including a second land formed thereon, the bonding sheet electrically connecting the first land to the second land with a conductive material, the bonding sheet comprising:
a front-side layer; a rear-side layer; and a middle layer, the middle layer has a higher viscosity than the front-side layer and the rear-side layer.

6. The bonding sheet according to claim 5, wherein the first land is electrically connected to the second land with the conductive material that is in a through-hole formed on the bonding sheet.

7. The bonding sheet according to claim 5, wherein the conductive material is a mixture of a metallic alloy powder, an activating material, and a bonding resin, wherein
the metallic alloy powder shapes the first land or the second land and an inter-metal compound and bond the first land and the second land together,
the activating material is used to convert the metallic alloy powder into a piece of metallic alloy,
the bonding resin is used to mix the metallic alloy powder and the activating material and give viscosity and printability, and
the bonding resin reacts with the activating material and hardens.

8. A laminated-circuit-board producing method performed by an apparatus for producing a laminated circuit board, the method comprising:
bonding a surface of a first wiring board on which a first land is formed to a surface of a bonding sheet that has a conductive material; and
bonding a surface of a second wiring board on which a second land is formed to a surface of the bonding sheet opposite to the surface to which the first wiring board is bonded in such a manner that the first land is bonded to the second land with the conductive material.

9. A laminated-circuit-board producing method performed by an apparatus for producing a laminated circuit board, the method comprising:
bonding a surface of a first wiring board on which a first land is formed to a surface of a bonding sheet that has a conductive material; and
bonding a surface of a second wiring board on which a second land is formed to a surface of the bonding sheet opposite to the surface to which the first wiring board is bonded; and
forming a through-hole on the bonding sheet at a position where the first land and the second land are bonded together and filling the through-hole with the conductive material, thereby electrically connecting the first land to the second land.

10. A bonding-sheet producing method performed by an apparatus for producing a bonding sheet that bonds a first wiring board including a first land formed thereon to a second wiring board including a second land formed thereon, the method comprising:
applying an epoxy resin on surfaces of polyester films;
inserting a glass fiber sheet made of a dielectric material between the surfaces of the polyester films that are covered with the epoxy resin, bonding them together with heat and pressure, and adjusting viscosity, thereby creating a prepreg; and
inserting a prepreg having a high viscosity between two prepregs having low viscosities, bonding them together with heat and pressure, thereby producing a bonding sheet having a front-side layer, a rear-side layer, and a middle layer, wherein the middle layer has a higher viscosity than the front-side layer and the rear-side layer.
